(19) United States
(12) Patent Application Publication
(10) Pub. No.: US 2015/0053259 A1
(43) Pub. Date: Feb. 26, 2015

(54) P-TYPE DOPING OF II-VI MATERIALS WITH RAPID VAPOR DEPOSITION USING RADICAL NITROGEN

(71) Applicant: Plant PV, Oakland, CA (US)

(72) Inventors: Brian E. Hardin, Berkeley, CA (US); James Randy Groves, Sunnyvale, CA (US); Stephen T. Connor, San Francisco, CA (US); Craig H. Peters, Oakland, CA (US)

(73) Assignee: PLANT PV, Oakland, CA (US)

(21) Appl. No.: 14/466,118

(22) Filed: Aug. 22, 2014

Related U.S. Application Data
(60) Provisional application No. 61/868,976, filed on Aug. 22, 2013.

(51) Int. Cl. H01L 31/18; H01L 31/0296; H01L 31/042; H01L 29/227; H01L 21/02

(52) U.S. Cl. CPC H01L 31/1828; H01L 29/227; H01L 21/02579; H01L 21/0262; H01L 31/1832; H01L 31/042; H01L 31/02963
USPC 136/255; 438/505; 204/298.02

(57) ABSTRACT

Apparatus and methods to incorporate p-type dopants in II-VI semiconducting layers are disclosed herein. In some embodiments, radical nitrogen is introduced in a physical vapor deposition apparatus operating at moderate pressures (e.g. 10⁻⁵ Torr to 100 Torr). The radical nitrogen allows for in-situ doping of II-VI materials, such as ZnTe, to degenerate levels.

### CROSS-REFERENCE TO RELATED APPLICATIONS

This application claims priority to U.S. Provisional Patent Application 61/868,976, filed Aug. 22, 2013, which is incorporated by reference herein.

### STATEMENT OF GOVERNMENT SUPPORT

This invention is made with Government support under contract number DE-EE0005332 awarded by the Department of Energy. The Government has certain rights to this invention.

### BACKGROUND OF THE INVENTION

### Field of the Invention

This invention relates generally to II-VI group semiconductors, and, more specifically, to advanced methods to rapidly dope same.

It is beneficial to dope II-VI materials to very high levels with p-type dopants using high throughput rapid thermal deposition techniques such as physical vapor transport and closed-space sublimation for photovoltaic cell (PV) applications. Stacks of highly (e.g., ≧10¹⁷ cm⁻³) p-type doped II-VI semiconducting layers can be used as a photoactive components in photovoltaic cells or can be used as components in tunnel junctions to connect sub-PV cells in tandem architectures, such as described in U.S. Patent Application Publication No. 020130192656, published Aug. 1, 2013, which is incorporated by reference in its entirety herein. For II-VI layers to be used in a tunnel junction, a doping level of at least 5×10¹⁸ cm⁻³ can be used, but doping levels greater than 10¹⁹ cm⁻³ are more typical.

It is possible to dope II-VI materials to very high levels with p-type dopants using high vacuum deposition techniques such as Molecular Beam Epitaxy (MBE) with a plasma generating radical nitrogen source at growth rates less than 0.0067 μm/min. Such slow growth rates, and concomitant low throughput rates along with generally high capital equipment costs prevent MBE from being economical for many large-scale optoelectronic devices such as photovoltaic cells.

It has been shown that using a nitrogen-containing atmosphere during RF sputtering of II-VI materials such as ZnTe can result in p-type films with a doping density of up to 5×10¹⁸ cm⁻³. However, a 30 minute anneal at 200° C. is used to complete the doping process. A likely reason for the non-degenerate doping density is that the plasma-generated ionic monatomic nitrogen species (e.g., N⁺) found in sputtering are much lower than the (N^{x} radicals) generated by an RF atomic nitrogen source. In addition, while MBE and MOCVD use remote plasma sources, sputtering uses the same plasma both to deposit ZnTe and to generate nitrogen species. This couples the deposition rate and doping density, limiting the maximum possible nitrogen incorporation. While it is possible to deposit films via sputtering at significantly higher rates than those possible with MBE and MOCVD, the doping levels achieved in ZnTe using this technique are not high enough to be useful for many components in PV cells.

Accordingly, it is desirable to develop high throughput deposition tools (e.g., greater than 0.3 μm/min) that are also capable of high p-type doping (e.g., >5×10¹⁸ cm⁻³) in II-VI materials, such as ZnTe.

### BRIEF DESCRIPTION OF THE DRAWINGS

The foregoing aspects and others will be readily appreciated by the skilled artisan from the following description of illustrative embodiments when read in conjunction with the accompanying drawings.

Some embodiments are illustrated by way of example and not limitations in the figures of the accompanying drawings, in which:

FIG. 1 is a diagram of a closed-space sublimation chamber in accordance with an embodiment of the invention.

FIG. 2 is a graph that shows p-type doping density of ZnTe as a function of nitrogen partial pressure according to some embodiments.

FIG. 3 illustrates a cross-sectional view of a single junction, II-VI based solar cell that incorporates a highly p-type doped II-VI layer as a rear contact according to some embodiments.

FIG. 4 illustrates a cross-sectional view of a single junction, solar-absorber perovskite-based solar cell that incorporates a highly p-type doped II-VI layer as a rear contact according to some embodiments.

FIG. 5 illustrates a cross-sectional view of at least a portion of a single junction solar-absorber perovskite solar cell, according to an embodiment of the invention.

FIG. 6 illustrates a cross-sectional view of a monolithically integrated, multijunction solar cell showing a first, silicon based, photovoltaic sub-cell, a tunnel heterojunction, and a second, II-VI based, photovoltaic sub-cell according to some embodiments.

FIG. 7 illustrates a cross-sectional view of a monolithically integrated, multijunction solar cell showing a first, silicon based, photovoltaic sub-cell, a tunnel heterojunction, and a second, solar-absorber perovskite-based, photovoltaic sub-cell according to some embodiments.

### SUMMARY

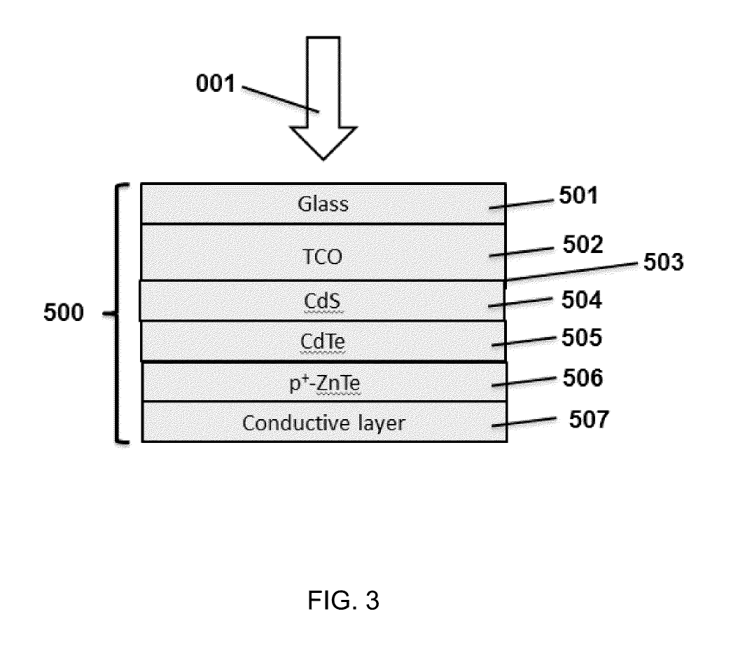

Various solar cell are disclosed. In one embodiment of the invention, as shown in FIG. 3, a solar cell has a glass substrate; a transparent conducting layer over the glass substrate; a n-type II-VI layer over the transparent conducting layer; a p-type II-VI layer; over the n-type II-VI layer; a ZnTe layer degenerately doped with monoatomic nitrogen over the p-type II-VI layer; and a metal contact over the ZnTe layer. There may be an optional high resistance layer between the transparent conducting layer and the n-type II-VI layer. The n-type II-VI layer may be CdTe or CdS. The p-type II-VI layer may be CdTe. The ZnTe layer may be polycrystalline.

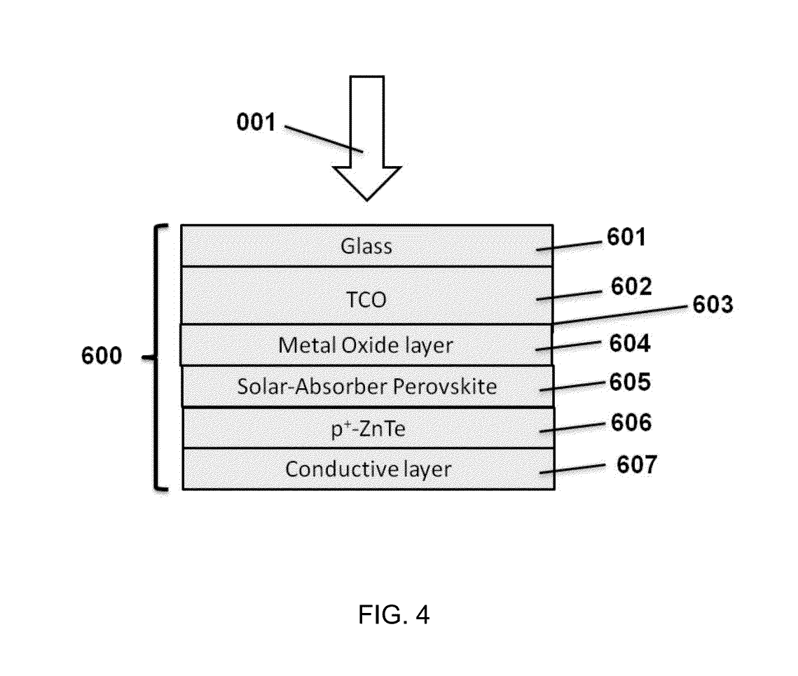

In another embodiment of the invention, as shown in FIG. 4, a solar cell has a glass substrate; a transparent conducting layer over the glass substrate; a metal oxide layer over the transparent conducting layer; a solar-absorber perovskite layer over the metal oxide layer; a ZnTe layer degenerately doped with monatomic nitrogen, the ZnTe layer over the solar-absorber perovskite layer; and a metal contact layer over the ZnTe layer. There may be an optional high resistance layer between the transparent conducting layer and the metal oxide layer. The solar metal oxide may be alumina or titania, or a combination thereof. The solar-absorber perovskite layer may contain alumina or titania nanoparticles.

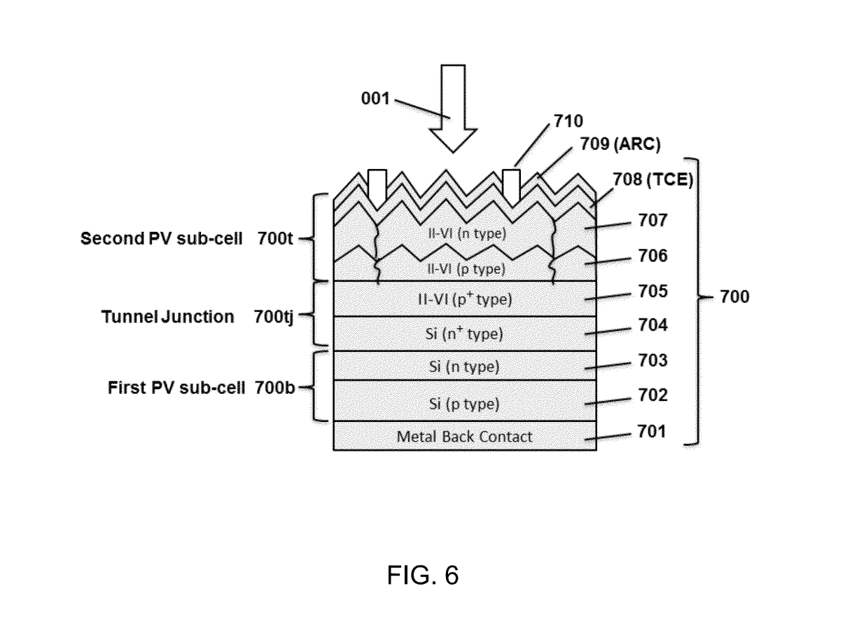

In another embodiment of the invention, as shown in FIG. 6, a monolithic, multijunction solar cell has a metal contact layer; a first photovoltaic sub-cell over the metal contact layer, the first photovoltaic sub-cell comprising; a Si p-type layer; and a Si n-type layer over the Si p-type layer; and a tunnel junction over the first photovoltaic sub-cell, the tunnel junction comprising: a degenerately doped n-type Si layer; and a ZnTe layer degenerately doped with monoatomic nitrogen, the ZnTe layer over the degenerately doped n-type Si layer; and a second photovoltaic sub-cell comprising: a multi-crystalline group II-VI p-type layer; and a multi-crystalline group II-VI n-type layer over the group II-VI p-type layer; and; a transparent conducting layer over the group II-VI n-type layer. There may be an optional high resistance layer between the transparent conducting layer and the metal oxide layer.

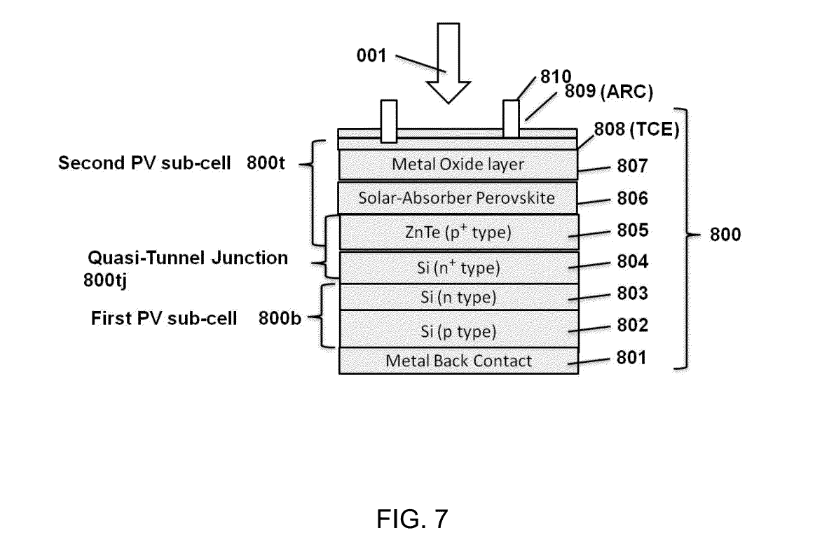

In another embodiment of the invention, as shown in FIG. 7, a monolithic, multijunction solar cell has a metal contact layer; a first photovoltaic sub-cell over the metal contact layer, the first photovoltaic sub-cell comprising; a p-type Si layer over the metal contact layer; and a n-type Si layer over the p-type Si layer; a tunnel junction over the first photovoltaic sub-cell comprising: a Si n-type degenerate layer; and a ZnTe layer degenerately doped with monatomic nitrogen over the Si n-type degenerate layer; and a second photovoltaic sub-cell over the tunnel junction, the second photovoltaic sub-cell comprising: a ZnTe layer degenerately doped with monatomic nitrogen; a solar-absorber perovskite layer over the ZnTe layer; and a metal oxide layer over the solar-absorber perovskite layer.

In one embodiment of the invention, a film deposition apparatus is disclosed. The apparatus has a pressurized chamber configured to have an operating pressure between 10⁻⁵ Torr to 100 Torr; a substrate holder in the chamber, the substrate holder configured to hold a substrate; at least one radical nitrogen generation source configured to provide a stream of radical nitrogen to a substrate in the substrate holder; one or more crucibles in the chamber, the crucibles configured to provide at least one Group II element and at least one Group VI element in the chamber; and a heat source configured to evaporate the Group II and Group VI elements for deposition as a Group II-VI layer onto a substrate in the substrate holder.

In one arrangement, the distance between the radical nitrogen generation source and a substrate in the substrate holder is between 5 and 25 cm. In another arrangement, the distance between the radical nitrogen generation source and a substrate in the substrate holder is about 10 cm. The substrate holder may maintain a substrate at a temperature between 100 and 650° C. Group II elements that can be used in the apparatus include one or more of Zn, Cd, and Hg. Group VI elements that can be used in the apparatus include one or more of Te, Se, and S. Layers that can be deposited using the apparatus include any of ZnTe, ZnSe, CdSe, CdS, CdₓZn_{y}Se, CdZnTe, CdS, CdTe, and combinations thereof. A Group II-VI layer formed in the apparatus may be doped with nitrogen to form a p-type layer. The radical nitrogen generation source may use a the gas composition that includes nitrogen and one or more of oxygen, argon, helium, and fluorine.

In another embodiment of the invention, a method of depositing a doped II-VI semiconductor layer is disclosed. The method involves the steps of: providing a deposition chamber; maintaining an operating pressure between 10⁻⁵ Torr and 100 Torr inside the deposition chamber; placing a substrate in a substrate holder in the deposition chamber; directing a stream of radical nitrogen onto the substrate; and providing one or more crucibles in the chamber, the crucibles configured to supply at least one Group II element and at least one Group VI element; and evaporating the Group II element(s) and the Group VI element(s) to deposit a Group II-VI layer onto the substrate; thereby forming a nitrogen-doped p-type II-VI semiconductor layer on the substrate.

The method of Claim B wherein the distance between the radical nitrogen generation source and a substrate in the substrate holder is between 5 and 25 cm. The Group II-VI layer composition may be any of ZnTe, ZnSe, CdSe, CdS, CdZnSe, CdZnTe, CdS, CdTe, and combinations thereof. The radical nitrogen may be created using a radio frequency (RF) plasma generator. The growth rate for the II-VI semiconductor layer may be between 0.30 μm/min and 10 μm/min or between 0.5 μm/min and 5 μm/min. The nitrogen doping density of the p-type II-VI semiconductor layer may be between 10¹⁸ cm⁻³ and 10²⁰ cm⁻³, between 5×10¹⁸ cm⁻³ and 10²⁰ cm⁻³, or between 5×10¹⁸ cm⁻³ and 10¹⁹ cm⁻³.

### DETAILED DESCRIPTION

It will be appreciated that numerous specific details are set forth in order to provide a thorough understanding of the example embodiments described herein. However, those of ordinary skill in the art of the embodiments described herein will understand and be able to practice the invention without these specific details. In other instances, well-known methods, procedures and components have not been described in detail as not to obscure the embodiments described herein. Furthermore, this description is not to be considered as limiting the scope of the embodiments described herein in any way, but rather as merely describing the implementation of the various embodiments described herein.

### DEFINITIONS

The term “solar-absorber perovskite” is used herein to mean a compound made up of heavy metals, halides, and small organic molecules, arranged in a perovskite crystal structure. An example of a solar-absorber perovskite is CH₃NH₃PbI₃₋ₓClₓ.

The following well-know elemental abbreviations are used throughout this disclosure.

| | | |
|---|---|---|
| C-Carbon | Hg-Mercury | Si-Silicon |
| Cd-Cadmium | I-Iodine | Sn-Tin |
| Cl-Chlorine | N-Nitrogen | Se-Selenium |
| Cs-Cesium | Pb-Lead | Te-Tellurium |
| H-Hydrogen | S-Sulfur | Zn-Zinc |

All publications referred to herein are incorporated by reference in their entirety for all purposes as if fully set forth herein.

Embodiments of the present disclosure provide a process to dope II-VI compounds with p-type dopants at moderate pressures using rapid (more than 0.3 μm/min) thermal deposition techniques such as physical vapor deposition, hot wall epitaxy, and closed-space sublimation. Such rapid vapor deposition tools have been proven to be low cost, high throughput processing techniques that are easily adapted to large scale manufacturing. In some arrangements, moderate pressures are considered to be between about 1×10⁻⁵ and 100 torr.

In some embodiments, the p-type doped layer is produced during rapid vapor deposition by addition of plasma with a significant radical nitrogen component. The radical nitrogen, which is produced via an electron cyclotron resonance (ECR), glow discharge (DC), or radio frequency (RF) plasma source, is incorporated into the II-VI thin film during growth. The level of nitrogen doping can be varied by changing the substrate temperature, gas composition, chamber pressure, growth rate, plasma energy, and/or II-VI stoichiometry. Methods for p-type doping II-VI materials using rapid thermal deposition techniques at moderate pressures are disclosed herein. Moderate to high (e.g., 10¹⁷ to 5×10¹⁹ cm⁻³) p-type doping level structures are used to make components for efficient photovoltaic cells, light emitting diodes, photodetectors, and the like.

Described herein are example embodiments of an apparatus and a process for in-situ p-type doping of II-VI semiconductors using radical nitrogen at moderate to high pressures using rapid thermal deposition tools. Some embodiments relate to the process of incorporating p-type dopants in II-VI semiconductors using high throughput, rapid thermal deposition processes such as closed-space sublimation using radical nitrogen at pressures between 10⁻⁵ and 100 Torr and deposition rates greater than 0.30 μm/min.

The embodiments of the invention, as disclosed herein, can be useful for growing many highly doped II-VI compounds. In one arrangement, the II-VI compound contains Zn. In another arrangement, the II-VI compound contains Cd. In another arrangement, the II-VI compound contains Hg. In another arrangement, the II-VI compound contains Te. In another arrangement, the II-VI compound contains Se. In another arrangement, the II-VI compound can be one or more of ZnTe, ZnSe, CdSe, CdS, CdZnSe, CdZnTe, CdS, and CdTe, and combinations thereof. In one arrangement, the II-VI compound is ZnTe. Depending on the substrate used, it is possible to grow both single crystal and polycrystalline layers.

The embodiments of the invention, as disclosed herein, can be used to grow and dope II-VI semiconductor layers with a variety of p-type dopants. In one arrangement, the dopant is nitrogen. In other arrangements, the p-type dopant may be arsenic.

The embodiments of the invention, as disclosed herein can provide p-type doping densities between 10¹⁷ cm⁻³ and 10²⁰ cm⁻³, between 10¹⁸ cm⁻³ and 10²⁰ cm⁻³, between 5×10¹⁸ cm⁻³ and 10²⁰ cm⁻³, between 5×10¹⁸ cm⁻³ and 10¹⁹ cm⁻³, or between 10¹⁷ cm⁻³ and 10¹⁸ cm⁻³.

Degenerate doping occurs when the Fermi level lies within the conduction band (for n-type materials) or valence band (for p-type materials) of the semiconductor. This occurs when the dopant concentration is high enough that the impurity atoms begin to interact with one another (e.g., are within the Bohr radius of one another). At this point the semiconductor can exhibit electrical behavior that resembles a metallic material. For ZnTe, degenerate doping is believed to occur for doping densities greater than 5×10¹⁸ cm⁻³. Degenerately doped, wide-band gap materials are important for many optoelectronic applications such as photovoltaic cells.

### Closed-Space Sublimation and Radical Nitrogen Source Set Up

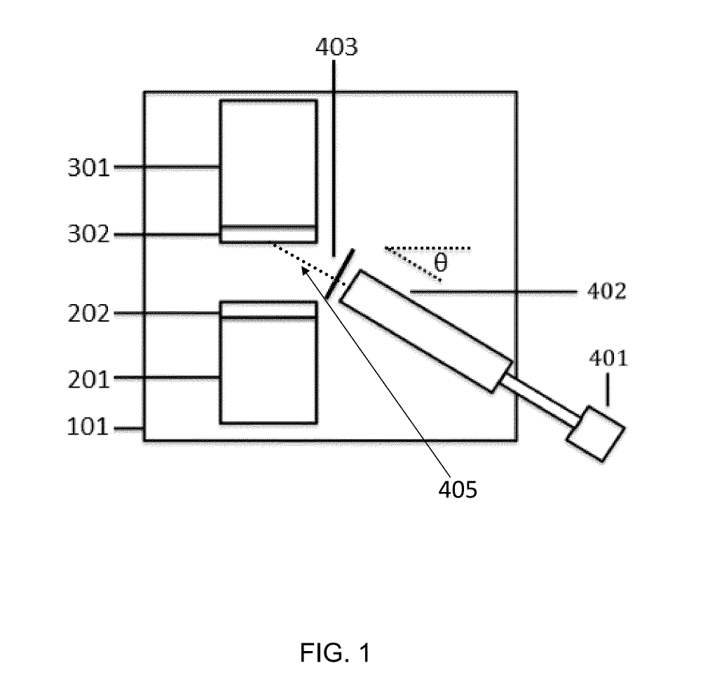

With reference to FIG. 1, in an example embodiment, there is a provided a diagram of a close-spaced sublimation chamber (CSS) 101 with a plasma generating radical nitrogen source 401 (also referred to as a gas source 401). The chamber 101 has a non-reactive crucible 202, such as a graphite crucible, configured to hold II-VI source material 202 (also referred to as a source 202) and a source heating element or apparatus 201 in contact with the crucible 202. The source material 202 may be a powder. The source heating element 201 is configured to heat source material 202 at least to a temperature at which it can evaporate. There is a substrate holder 302 in thermal contact with a substrate heating element or apparatus 301. The substrate holder 302 is configured to hold a substrate, and the substrate heating element 301 is configured to maintain the substrate at a desired temperature. There is a radical nitrogen generator 402 connected to a gas source 401. The gas source 401 may contain 100% nitrogen or mixtures of nitrogen with other elements such as argon or helium as well as small amounts of oxidizers such as oxygen and fluorine. In the embodiment referenced in FIG. 1 the separation distance between the substrate 302 and the source material 202 is typically between 2 mm and 50 mm, but may be even greater than 250 mm depending on the chamber pressure. The angle of the radical nitrogen generator 402 relative to the substrate 302, which is shown as θ in FIG. 1, can range from 0.5° to 89° in the close-spaced sublimation system and is chosen based on substrate size and separation distance between the source 202 and substrate 302. There is also a shutter 403 that opens and closes to control the flow of radical nitrogen. The distance between the exit port (not shown) of the radical nitrogen generator 402 and a substrate (not shown) in the substrate holder 302 is indicated by dotted line 405.

The distance between the radical nitrogen generator and the substrate is determined by the velocity and radical nitrogen species lifetime. For further information about this, see Sato, “Nitrogen Radical Densities During GaN Growth by Molecular Beam Epitaxy, Plasma-Assisted Metalorganic Chemical Vapor Deposition, and Conventional Metalorganic Chemical Vapor Deposition,” Solid-State Electronics 41, No. 2, p 223-226 (included by reference herein), which teaches that the deactivation of radical nitrogen species requires two radical nitrogens and body to transfer the heat. The deactivation rate (and subsequent lifetime) is dependent on the concentration of radical nitrogen species. In some arrangements, the length of the dotted line is equivalent to the radical nitrogen lifetime times the velocity. In various embodiments, the length of the dotted line is between 5 and 25 cm, between 8 and 15 cm, between 9 and 11 cm, or about 10 cm.

In some arrangements, growth rates for II-VI semiconductor films are between 0.30 μm/min and 10 μm/min, or between 0.5 μm/min and 5 μm/min.

### Doping and Deposition of ZnTe Thin Films

In some embodiments, ZnTe is grown onto a sapphire substrate held in substrate holder 302 using close-spaced sublimation as shown in FIG. 1. The sapphire substrate is loaded onto the substrate holder 302, and the CSS chamber 101 is pumped down to 10⁻⁶ Torr prior to deposition. In some embodiments, radical nitrogen generation is provided by the radical nitrogen generator 402 that is, for example, a radio frequency (RF) plasma source (e.g., Mantis 600 W RF Atom Source). In other arrangements, the radical nitrogen generator is a direct current (DC) plasma source or an electron cyclotron resonance (ECR) plasma generation source. First, highly pure nitrogen gas, provided by the gas source 401, enters the CSS 101 through the radical nitrogen generator 402, increasing the chamber pressure to 2×10⁻⁵ Torr in a continuous flow. The RF plasma source (e.g., radical nitrogen generator 402) is then turned on, using power levels between 75 and 500 W, and the radical nitrogen is generated. The chamber pressure can be controlled from 10⁻⁵ to 100 Torr by adjusting a secondary nitrogen source (not shown). In other arrangements. the gas source 401 may provide additional gases such as oxygen, argon, helium, fluorine, and combinations thereof.

ZnTe is deposited onto the substrate 302 by heating ZnTe powder in the graphite crucible 202 between 650-750° C. using the source heating apparatus 201, which, in some arrangements, is a 600 W halogen light bulb. The temperature of the substrate 302 can be controlled through the substrte heating apparatus 301, which is similar to the source heating apparatus 201. Growth of ZnTe films can occur with substrate temperatures between 100 and 650° C. at chamber pressures between 10⁻⁵ and 100 Torr. During ZnTe deposition the shutter 403 is open, allowing radical nitrogen to become absorbed into the ZnTe layer during deposition. This results in the incorporation of monatomic nitrogen into the ZnTe film, resulting in a nitrogen-doped, p-type ZnTe film. The ZnTe deposition rate can vary from 0.20 μm/min to 10 μm/min or from 0.5 μm/min to 5 μm/min based on the substrate/source separation distance, chamber pressure, source temperature, and/or substrate temperature. The typical thickness of ZnTe thin films deposited using this method ranges from 0.1 μm to 10 μm.

### Effects of Nitrogen Partial Pressure on P-Type Doping of ZnTe

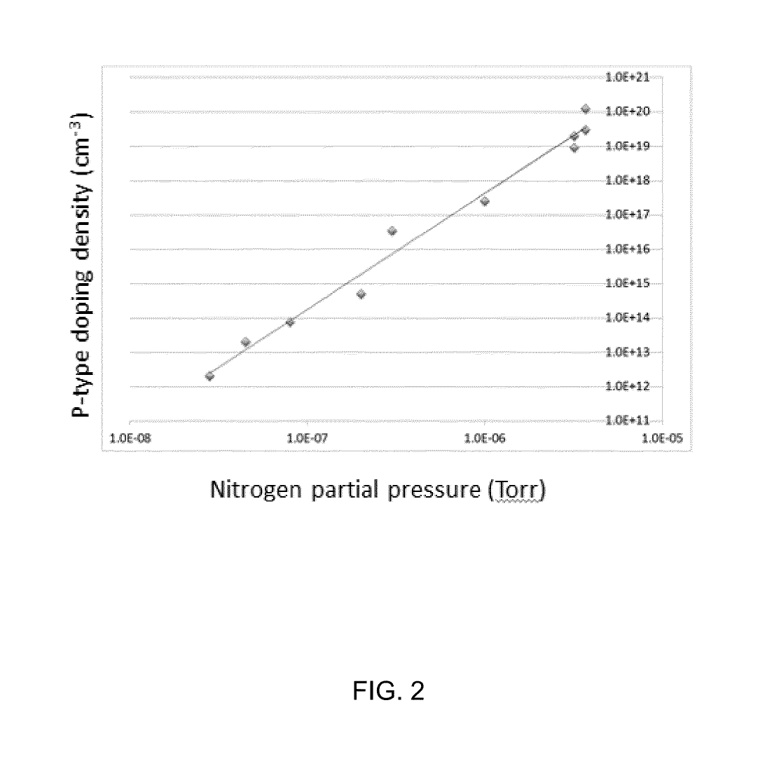

FIG. 2 is a graph that shows p-type doping density of ZnTe as a function of the partial pressure of nitrogen during deposition at temperatures between 100 and 300 C, according to some embodiments. The nitrogen was mixed with argon at various ratios and the partial pressures were measured in-situ using a residual gas analyzer. For pure nitrogen at a chamber pressure of 2×10⁻⁵ Torr, the ZnTe was degenerately doped p-type. By varying the nitrogen pressure (i.e., flow rate) it was possible vary the p-type doping levels by seven orders of magnitude. As shown in FIG. 2 polycrystalline ZnTe films regularly achieve p-type doping densities greater than 10¹⁹ cm⁻³, which is an order of magnitude higher than previously reported polycrystalline ZnTe films grown via sputter deposition. In some instances p-type doping densities of more than 10²⁰ cm⁻³ were achieved for ZnTe.

ZnTe films may be doped over a wide processing window, with a variety of substrate temperatures (e.g., 300-400 C) and chamber pressures (2×10⁻⁵ to 5×10⁻³ Torr), using the vapor deposition process disclosed herein. In various arrangements, the nitrogen doping density in such films is between 10¹⁷ cm⁻³ and 10²⁰ cm⁻³, between 10¹⁸ cm⁻³ and 10²⁰ cm⁻³, between 5×10¹⁸ cm⁻³ and 10²⁰ cm⁻³, or between 5×10¹⁸ cm⁻³ and 10¹⁹ cm⁻³.

Single Junction, II-VI Based Solar Cells that Incorporates a Highly Doped II-VI Layer

With reference to FIG. 3, in an example embodiment, a cross-sectional view of at least a portion of a single junction II-VI solar cell 500 is shown. The II-VI single junction solar cell 500 has a glass substrate 501, a transparent conducting oxide layer 502 such as fluorine doped tin oxide, and optionally a high resistance layer 503, such as ZnSnOₓ, to prevent electrical shunting and chemical reactions, an n-type window layer 504 such as CdS, a p-type photoactive layer 505 such as CdTe, a rear contact layer 506 such as degenerately doped ZnTe, and a conductive layer 507 such as graphite or metal (e.g., aluminum, nickel) to transport charges. As an example, such a solar cell may have a 500 nm thick fluorine doped tin oxide, transparent conducting oxide layer 502 grown on a 3 mm thick glass 501, a 20 nm thick high resistance layer 503, such as ZnSnOₓ, a 2-30 nm thick CdS layer as the window layer 504, a 2 μm CdTe as the p-type layer 505, and a 300 nm thick, degenerately-doped ZnTe layer 506. The degenerately doped ZnTe layer 506 can range in thickness from 5 nm to 5 μm. As shown in FIG. 3, the solar cell 500 receives incident sunlight or other light 001 through the glass 501.

For single junction, II-VI PV cells, a highly doped rear contact layer 506 is highly desirable to improve charge transfer from the p-type photoactive layer 505 to the conductive layer 507. The ability to dope ZnTe with nitrogen to levels greater than 5×10¹⁸ cm⁻³ during rapid thermal deposition (as described herein) in the single junction solar cells can increase the open-circuit voltage and improve contact resistance at the back interface (e.g. graphite or metal contact layer 507).

Single Junction, Superstrate Perovskite Based Solar Cells that Incorporates a Highly Doped II-VI Layer

With reference to FIG. 4, in an example embodiment, a cross-sectional view of at least a portion of a single junction perovskite solar cell 600 in a superstrate configuration is shown. The perovskite single junction solar cell 600 has a glass layer 601, a transparent conducting oxide layer 602 such as fluorine doped tin oxide and an optional high resistance layer 603, such as ZnSnOₓ, to prevent electrical shunting and chemical reactions, an n-type metal oxide layer 604 such as TiO₂, a solar-absorber perovskite layer 605 such as CH₃NH₃PbI₃₋ₓClₓ, a hole transporting layer 606 such as degenerately doped ZnTe, and a conductive layer 607 such as graphite or metal (e.g. silver, aluminum, nickel) to transport charges. As an example, the solar cell may have a 500 nm thick fluorine doped tin oxide layer transparent conducting oxide layer 602 grown on 3 mm thick glass 601, a 20 nm thick high resistance layer 603, such as ZnSnOₓ, 2-500 nm thick TiO₂ as n-type layer 604, 300 nm-2 μm thick solar-absorber perovksite as the p-type layer 605, a 300 nm thick degenerately-doped ZnTe layer 606, and a conductive layer 607, such as an evaporated metal layer. Such an evaporated metal layer 607 may have a thickness between 1 and 5 μm, between 2 and μm, or about 3 μm. It should be noted that many solar-absorber perovskite materials undergo phase transformations at temperatures above 150° C.; therefore it is best if layers deposited after the solar-absorber perovskite material are done so at temperatures less than 150° C. The degenerately doped ZnTe layer 606 can range in thickness from 5 nm to 5 μm. As shown in FIG. 4, the solar cell 600 receives incident sunlight or other light 001 through the glass 601. Such a superstrate-configuration solar cell 600 is assembled by starting with the glass layer 604 onto which the other layers are stacked.

The solar-absorber perovskite layer 605 can be made from a variety of materials including CsSnI₃ or CH₃NH₃PbI₃₋ₓClₓ. Reference is made to the following articles which provide additional details regarding example suitable materials and fabrication techniques for solar-absorber perovskites: Michael M. Lee et al., “Efficient Hybrid Solar Cells Based on Meso-Superstructured Organometal Halide Perovskites,” Science 338, 643-647, DOI: 10.1126/science.1228604 (2012); In Chung et al., “All-solid-state Dye-sensitized Solar Cells with High Efficiency,” Nature 485, 486-489, DOI: 10.1038/nature11067 (May 24, 2012); and Hui-Seon Kim et al., “Lead Iodide Perovskite Sensitized All-Solid-State Submicron Thin Film Mesoscopic Solar Cell with Efficiency Exceeding 9%,” Scientific Reports 2, 591, 1-7, DOI: 10.1038/srep00591 (2012). The solar-absorber perovskite layer 605 may consist solely of solar-absorber perovskite material or may be a mixture of the solar-absorber perovskite material inside a mesostructured, metal oxide framework such as nanoparticle-based TiO₂ or Al₂O₃. Currently, solar-absorber perovskite based solar cells use organic hole conductors (e.g., 2,2′,7,7′-tetrakis(N,N-di-p-methoxypheny-amine)-9,9′-spirobifluorene, also known as spiro-MeOTAD) for the hole transporting layer 606 to make electrical contact to the solar-absorber perovskite. However, these materials are known to require post processing with oxygen to improve doping and do not have a high mobility, which increases the series resistance of the solar cell resulting in a lower fill factor and power conversion efficiency. Furthermore, organic hole conductors have not been proven to be stable over the expected 25 year lifetime of a solar cell. It is instead beneficial to use a highly doped p-type layer that does not require post-processing (e.g., oxygen exposure), that is stable, and can be highly doped to reduce series resistance. Furthermore, ZnTe can be transparent in the near infrared (NIR); by using a transparent conductive layer 607 it is possible to make bi-facial solar cells that allow NIR photons to pass through enabling the single junction solar-absorber perovksite solar cell to be used as the top cell for a mechanically stacked tandem PV device.

Single Junction, Substrate Perovskite Based Solar Cells that Incorporates a Highly Doped II-VI Layer

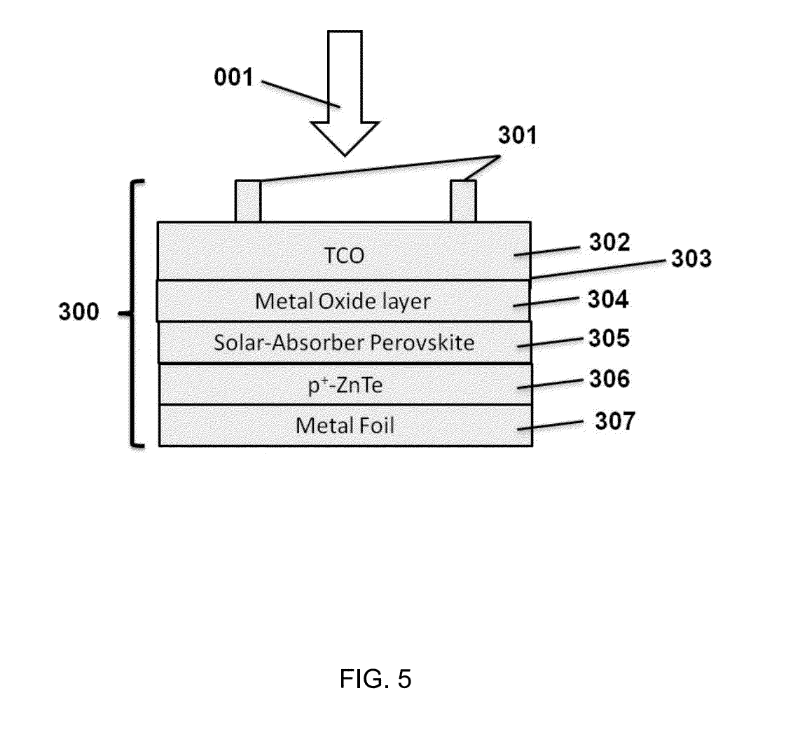

With reference to FIG. 5, in an example embodiment, a cross-sectional view of at least a portion of a single junction perovskite solar cell 300 that has a substrate configuration is shown. The perovskite single junction solar cell 300 contains a metal foil (e.g. aluminum, nickel, or stainless steel) layer 307, a hole transporting layer 306 such as degenerately doped p-type ZnTe, a solar-absorber perovskite layer 305 such as CH₃NH₃PbI₃₋ₓClₓ, an n-type metal oxide layer 304 such as TiO₂, an optional electron transport layer (ETL) 303, a transparent conducting oxide layer 602 such as fluorine doped tin oxide or indium tin oxide, and metal contacts 301 to transport charge. Such a substrate-configuration solar cell 300 is assembled by starting with the metal foil layer 307 as a substrate onto which the other layers are stacked. The metal foil layer 307 may have a thickness between 100 and 800 μm, between 150 and 600 μm, or between 200 and 200 μm.

It should be noted that many solar-absorber perovskite materials undergo phase transformations at temperatures above 150° C.; therefore it is best if layers deposited after the solar-absorber perovskite material are done so at temperatures less than 150° C. As an example, the solar cell shown in FIG. 5 may be formed by first evaporating 0.3-3 μm of degenerately doped p-type ZnTe 306 onto a smooth stainless steel foil 307. A 300 nm-2 μm thick solar-absorber perovksite layer 305 can be deposited onto the ZnTe layer 306 via solution or evaporation. A 2-500 nm thick TiO₂ as metal oxide layer 304 can be deposited via sputtering, The electron transport layer 303 can be deposited via solution deposition (such as with a poly-ethyleneimine ethoxylated solution), and a 300 nm TCO layer 302 can be formed by sputtering of indium tin oxide. The solar cell 300 is configured to receive incident sunlight or other light 001 as shown in FIG. 5. Such a solar cell with a substrate configuration helps to ensure that after deposition of the solar-absorber perovskite 305, subsequent processing steps can easily be performed at temperatures less than 150° C.

The solar-absorber perovskite layer 305 can be made from a variety of materials including CsSnI₃ or CH₃NH₃PbI₃₋ₓClₓ. Reference is made to the following articles which provide additional details regarding example suitable materials and fabrication techniques for solar-absorber perovskites: Michael M. Lee et al., “Efficient Hybrid Solar Cells Based on Meso-Superstructured Organometal Halide Perovskites,” Science 338, 643-647, DOI: 10.1126/science.1228604 (2012); In Chung et al., “All-solid-state Dye-sensitized Solar Cells with High Efficiency,” Nature 485, 486-489, DOI: 10.1038/nature11067 (May 24, 2012); and Hui-Seon Kim et al., “Lead Iodide Perovskite Sensitized All-Solid-State Submicron Thin Film Mesoscopic Solar Cell with Efficiency Exceeding 9%,” Scientific Reports 2, 591, 1-7, DOI: 10.1038/srep00591 (2012). The solar-absorber perovskite layer 305 may consist solely of solar-absorber perovskite material or may be a mixture of the solar-absorber perovskite material inside a mesostructured, metal oxide framework such as nanoparticle-based TiO₂ or Al₂O₃. Currently, solar-absorber perovskite based solar cells use organic hole conductors (e.g., 2,2′,7,7′-tetrakis(N,N-di-p-methoxypheny-amine)-9,9′-spirobifluorene, also known as spiro-MeOTAD) for the hole transporting layer 306 to make electrical contact to the solar-absorber perovskite. However, these materials are known to require post processing with oxygen to improve doping and do not have a high mobility, which increases the series resistance of the solar cell resulting in a lower fill factor and power conversion efficiency. Furthermore, organic hole conductors have not been proven to be stable over the expected 25 year lifetime of a solar cell. It is instead beneficial to use a highly doped p-type layer that does not require post-processing (e.g., oxygen exposure), that is stable, and can be highly doped to reduce series resistance. Furthermore, ZnTe can be transparent in the near infrared (NIR) which allows for an increased light harvesting of photons reflected off of the metal foil.

Finally, one of the greatest challenges of growing substrate perovskite solar cells is finding a p-type layer 306 that can survive the additional processing steps. The high thermal and chemical stability of ZnTe versus organic hole conductors such as spiro-MeOTAD enables the fabrication of substrate based perovskite solar cells.

Tandem II-VI/Si Based Solar Cells that Incorporates a Highly Doped II-VI Layer

With reference to FIG. 6, in an example embodiment, a cross-sectional view of at least a portion of a monolithic, multijunction solar cell 700 is shown. The solar cell 700 has a narrow band gap, silicon (Si) based photovoltaic sub-cell 700b (also referred to as a first PV sub-cell), a tunnel heterojunction 700tj (also referred to as a tunnel junction), and a wide band gap, II-VI based photovoltaic sub-cell 700t (also referred to as a second PV sub-cell or top cell). The sub-cell 700b has a Si n-type layer 703 and a Si p-type layer 702 over a metal back contact layer 701. The tunnel junction 700tj has a II-VI degenerately doped p-type layer 705 and a degenerately doped n-type Si layer 704. The sub-cell 700t has a II-VI n-type layer 707 and a II-VI p-type layer 705.

When incident light 001 is directed to the top of the multijunction solar cell 700, photovoltaic sub-cell 700t absorbs photons that have energy greater than the band gap of the multi-crystalline, II-VI n-type emitter 707 and multi-crystalline, II-VI p-type base 706 layers. This allows lower energy photons (those with energy less than the band gap of the emitter 707 and base 706 layers) to pass through the tunnel junction 700tj. Thus any photons with energies greater than the band gap of the single crystal n-type emitter 703 and single crystal p-type base 702 layers can be absorbed by the silicon based photovoltaic sub-cell 700b. In this example, photocurrent travels in series through the II-VI based sub-cell 700t, tunnel junction 700tj, and the Si based sub-cell 700b.

The multi junction solar cell can also contain a transparent conducting electrode (TCE) layer 708 over the second sub-cell 700t. The TCE layer 708 may be made of indium doped tin oxide to reduce series resistance as charges travel from the n-type layer 707 to metal contacts 710. The metal back contact 701 is typically made using aluminum. The multijunction solar cell may also have an anti-reflective coating (ARC) 709 such as silicon nitride to reduce reflection losses. In an example embodiment, the tandem II-VI/Si solar cell has, in stacking order, a 150 μm thick silicon substrate with a base layer doped to 10¹⁷ cm⁻³ p-type 702, an emitter layer doped 10¹⁹ cm⁻³ n-type 703, a 2-50 nm thick degenerately doped n-type Si layer 704, a 2 μm thick, degenerately-doped, ZnTe layer 705, a 2 μm thick p-type CdZnTe layer 706, a 20-50 nm thick CdS film as the n-type layer 707, an optional 10-50 nm layer of intrinsic ZnO (not shown in the figure), and a 20-300 nm thick layer of aluminum doped ZnO as the transparent conducting electrode layer 708. The thickness of the ZnTe layer can range from 1 nm to 5 μm.

The highly p-type doped II-VI tunnel junction layer 700tj can be fabricated using the deposition process described above with respect to FIG. 1. The highly p-type doped (e.g., greater than 5×10¹⁸ cm⁻³) II-VI tunnel junction layer 700tj adds to the efficiency of the solar cell. The method of nitrogen doping of ZnTe to levels greater than 10¹⁸ cm⁻³ during rapid vapor deposition in multijunction solar cells reduces the series resistance between the PV-sub cells and can result in higher rectification and increased power conversion efficiency.

Tandem Solar-Absorber Perovskite/Si Based Solar Cells that Incorporate a Highly Doped II-VI Layer

With reference to FIG. 7, in an example embodiment, a cross-sectional view of at least a portion of a monolithic, multijunction solar cell 800 is shown. The cell 800 has a narrow band gap, silicon (Si) based photovoltaic sub-cell 800b (also referred to as a first PV sub-cell), a quasi-tunnel heterojunction 800tj, and a wide band gap, solar-absorber perovskite based photovoltaic sub-cell 800t (also referred to as a second PV sub-cell or top cell). The photovoltaic sub-cell 800t is a p-i-n structure where the n-type metal oxide 807 layer can be TiO₂, the photoactive layer 806 is a solar-absorber perovskite that can be CH₃NH₃PbI₃₋ₓClₓ, and the p-type layer 805 can be ZnTe. The quasi-tunnel junction 800t has the degenerately doped p-type ZnTe layer 805 over a degenerately doped n-type silicon layer 804. The first sub-cell 800b has a Si n-type layer 803 over a Si p-type layer 802. There is a metal back contact layer 801 in contact with the Si p-type layer of the first sub-cell 800b.

When incident light 001 is directed as shown in the figure, photovoltaic sub-cell 800t absorbs the photons that have energy greater than the band gap of the solar-absorber perovskite layer 806 and the p-type layer 805. The lower energy photons (those with energy less than the band gap of the sub-cell 800t) pass through the tunnel heterojunction 800tj, which has a ZnTe layer 805 and a n-type Si layer 804, so that photons with energies greater than the band gap of the single crystal n-type emitter 803 and single crystal p-type base 802 layers can be absorbed by the silicon based photovoltaic sub-cell 800b. In this example, photocurrent travels in series through the II-VI based sub-cell 800t, tunnel junction 800tj, and the Si based sub-cell 800b.

The multi junction solar cell can also contain a transparent conducting electrode layer (TCE) 808 that is made of indium doped tin oxide to reduce series resistance as charges travel from the n-type layer 807 to metal contacts 810. The multijunction solar cell may also contain an anti-reflective coating (ARC) 809 such as silicon nitride to reduce reflection losses. Metal back contact 801 is typically made using aluminum. In an example embodiment, the tandem solar-absorber perovskite solar cell may have a 150 μm thick silicon substrate 802 with a base layer doped to 10¹⁷ cm⁻³ p-type, an emitter layer 803 doped 10¹⁹ cm⁻³ n-type, a 2-50 nm thick degenerately doped n-type Si layer 804, a 2 μm thick, degenerately doped, ZnTe layer 805, a 0.3-2 μm thick perovskite layer 806, a 20-50 nm thick TiO₂ layer 807 and a 20-300 nm thick layer of indium tin oxide as the transparent conducting electrode layer 808. The thickness of the ZnTe layer can range from 1 nm to 5 μm.

The solar-absorber perovskite layer 806 can be made from a variety of materials including CsSnI₃ or CH₃NH₃PbI₃₋ₓClₓ. Reference is made to the following articles which provide additional details regarding example suitable materials and fabrication techniques for solar-absorber perovskites: Michael M. Lee et al., “Efficient Hybrid Solar Cells Based on Meso-Superstructured Organometal Halide Perovskites,” Science 338, 643-647, DOI: 10.1126/science.1228604 (2012); In Chung et al., “All-solid-state Dye-sensitized Solar Cells with High Efficiency,” Nature 485, 486-489, DOI: 10.1038/nature11067 (May 24, 2012); and Hui-Seon Kim et al., “Lead Iodide Perovskite Sensitized All-Solid-State Submicron Thin Film Mesoscopic Solar Cell with Efficiency Exceeding 9%,” Scientific Reports 2, 591, 1-7, DOI: 10.1038/srep00591 (2012). The solar-absorber perovskite layer may consist solely of solar-absorber perovskite or may be a mixture of the solar-absorber perovskite inside a mesostructured, metal oxide framework such as nanoparticle based TiO₂ or Al₂O₃. Currently, solar-absorber perovskite based solar cells exclusively use organic hole conductors for the hole transporting layer 606 to make electrical contact to the perovskite. However, these materials are known to require oxygen to improve doping and do not have a high mobility, which increases the series resistance of the solar cell resulting in a lower fill factor and power conversion efficiency. It is instead beneficial to use an inorganic, highly p-type layer as the p-type layer 805 because it has lower series resistance and allows additional layers (e.g., 806-810) to be processed at higher temperatures that the organic hole conductors would not survive (e.g., >250 C). Furthermore, ZnTe is more transparent in the near infrared than spiro-MeOTAD and can be degenerately doped, which is a requirement for the p-type layer 805 to make an efficient monolithically integrated tandem solar cell.

Degenerate ZnTe layers may also be used in near-infrared detectors, radiation detectors, and/or light emitting diodes. It should also be noted that CdZnTe may be an alternative highly p-doped layer, being doped to 10¹⁷ cm⁻³ with a band gap between 1.7 to 2.0 eV. Those skilled in the art of solar cell architecture will understand the many advantages in using a degenerate doped ZnTe layer as the high p-type layer for other II-VI and solar-absorber perovskite based PV cell architectures.

In this manner, degenerate doping of Group II-VI material is achieved at a high deposition rate and at moderate pressures. A thermal evaporative technique is applied to achieve the degenerately doped Group II-VI layer or thin film. In some embodiments, the resulting thin film may contain degenerately p-type doped ZnTe.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A film deposition apparatus comprising:
a pressurized chamber configured to have an operating pressure between 10⁻⁵ Torr to 100 Torr;
a substrate holder in the chamber, the substrate holder configured to hold a substrate; at least one radical nitrogen generation source configured to provide a stream of radical nitrogen to a substrate in the substrate holder;
one or more crucibles in the chamber, the crucibles configured to provide at least one Group II element and at least one Group VI element in the chamber; and
a heat source configured to evaporate the Group II and Group VI elements for deposition as a Group II-VI layer onto a substrate in the substrate holder.

2. The film deposition apparatus of claim 1 wherein the distance between the radical nitrogen generation source and a substrate in the substrate holder is between 5 and 25 cm.

3. The film deposition apparatus of claim 1 wherein the distance between the radical nitrogen generation source and a substrate in the substrate holder is about 10 cm.

4. The film deposition apparatus of claim 1, wherein the substrate holder maintains a substrate at a temperature between 100 and 650° C.

5. The film deposition apparatus of claim 1, wherein the Group II element is any one or more of Zn, Cd, and Hg.

6. The film deposition apparatus of claim 1, wherein the Group VI element is any one or more of Te, Se, and S.

7. The film deposition apparatus of claim 1, wherein Group II-VI layer composition is selected from the group consisting of ZnTe, ZnSe, CdSe, CdS, CdₓZn_{y}Se, CdZnTe, CdS, CdTe, and combinations thereof.

8. The film deposition apparatus of claim 1, wherein the Group II-VI layer composition is ZnTe.

9. The film deposition apparatus of claim 1, wherein the Group II-VI layer is doped with nitrogen to form a p-type layer.

10. The film deposition apparatus of claim 1, wherein the radical nitrogen generation source uses a the gas composition comprising nitrogen and one or more selected from the group consisting of oxygen, argon, helium, and fluorine.

11. A method of depositing a doped II-VI semiconductor layer, comprising the steps of:
a) providing a deposition chamber;
b) maintaining an operating pressure between 10⁻⁵ Torr and 100 Torr inside the deposition chamber;
c) placing a substrate in a substrate holder in the deposition chamber;
d) directing a stream of radical nitrogen onto the substrate;
e) providing one or more crucibles in the chamber, the crucible(s) configured to supply at least one Group II element and at least one Group VI element; and
f) evaporating the Group II element(s) and the Group VI element(s) to deposit a Group II-VI layer onto the substrate;
thereby forming a nitrogen-doped p-type II-VI semiconductor layer on the substrate.

12. The method of claim 11 wherein the distance between the radical nitrogen generation source and a substrate in the substrate holder is between 5 and 25 cm.

13. The method of claim 11, wherein the Group II-VI layer composition is selected from the group consisting of ZnTe, ZnSe, CdSe, CdS, CdZnSe, CdZnTe, CdS, CdTe, and combinations thereof.

14. The method of claim 11, wherein the Group II-VI composition is ZnTe.

15. The method of claim 11, wherein the radical nitrogen is created using a radio frequency (RF) plasma generator.

16. The method of claim 11, wherein a growth rate for the II-VI semiconductor layer is between 0.30 μm/min and 10 μm/min.

17. The method of claim 11, wherein a growth rate for the II-VI semiconductor layer is between 0.5 μm/min and 5 μm/min.

18. The method of claim 11, wherein a nitrogen doping density of the p-type II-VI semiconductor layer is between 10¹⁸ cm⁻³ and 10²⁰ cm⁻³.

19. The method of claim 11, wherein a nitrogen doping density of the p-type II-VI semiconductor layer is between 5×10¹⁸ cm⁻³ and 10²⁰ cm⁻³.

20. The method of claim 11, wherein a nitrogen doping density of the p-type II-VI semiconductor layer is between 5×10¹⁸ cm⁻³ and 10¹⁹ cm⁻³.

21. A solar cell, comprising:
a glass substrate;
a transparent conducting layer over the glass substrate;
a n-type II-VI layer over the transparent conducting layer;
a p-type II-VI layer; over the n-type II-VI layer;
a ZnTe layer degenerately doped with monatomic nitrogen over the p-type II-VI layer; and
a metal contact over the ZnTe layer.

22. The solar cell of claim 21 further comprising an optional high resistance layer between the transparent conducting layer and the n-type II-VI layer.

23. The solar cell of claim 21 wherein the n-type II-VI layer comprises CdTe or CdS.

24. The solar cell of claim 21 wherein the p-type II-VI layer comprises CdTe.

25. The solar cell of claim 21 wherein the ZnTe layer is polycrystalline.
